(19) United States
(12) Patent Application Publication
(10) Pub. No.: US 2004/0217466 A1
(43) Pub. Date: Nov. 4, 2004

(54) Function module and its manufacturing method

(76) Inventor: Wen-Yen Lin, Taoyuan City (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(21) Appl. No.: 10/827,194

(22) Filed: Apr. 19, 2004

(30) Foreign Application Priority Data
Apr. 29, 2003 (TW) 92109973

(51) Int. Cl. H01L 21/44; H01L 23/10

(52) U.S. Cl. 257/706; 438/125; 257/712

(57) ABSTRACT

A function module and its manufacturing method. The function module includes a circuit board, a first device, a second device, a planarization member, and a plate-type heat dissipation device. The circuit board includes a surface. The first device is disposed on the surface. The second device is disposed on the surface, and the height of the second device is higher than the height of the first device. The planarization member, including a flat surface, is disposed on the surface in a manner such that the planarization member surrounds the first device and the second device. The height of the flat surface is not less than the height of the second device. The plate-type heat dissipation device is disposed on the flat surface.

### BACKGROUND OF THE INVENTION

1. Field of the Invention

The invention relates to a function module and its manufacturing method; in particular, to a method that can easily place a plate-type heat dissipation device on a circuit board including a plurality of devices with varying heights.

2. Description of the Related Art

Generally, a printed circuit board of an electronic apparatus includes many electronic devices and operating circuits distributed thereon. When the electronic apparatus is operated, electronic devices will produce heat and increase temperature inside the electronic apparatus such that the efficiency of the electronic device may be inhibited, and an excessive temperature increase may lead to device malfunction. Therefore, a heat dissipation device is necessary on printed circuit boards for dissipation of produced heat.

In addition, as semiconductor technology process has evolved, the operating speeds thereof have increased accordingly, such that a single electronic device may now incorporate multiple functions. However, due to such designs, it is difficult to simultaneously control heat dissipation, signal quality, and electromagnetic radiation in the electronic device.

As stated above, electronic devices communicate via the circuit board. Referring to FIG. 1a and FIG. 1b, in a computer system 10, electronic devices, such as a central processing unit (CPU) 1, chipset 2, graphics processing unit (GPU) or accelerated graphics port (AGP) 3, or dynamic random access memory (DRAM) 4, are disposed in different areas of a motherboard 7. To solve heat dissipation problems for each electronic device, a conventional solution is provided for each electronic device.

For example, a combination of a heat dissipation fin, a heat pipe, and a fan is typically employed for the CPU. The heat dissipation fin and/or the fan are usually used for the chipset or the GPU. However, the conventional solution does not adequately solve the heat dissipation problem with regard to a motherboard with a plurality of electronic devices thereon. Thus, a more efficient heat dissipation device is required. However, such solutions are conventionally only suitable for use on a flat surface. That is, the varying heights of each electronic device rule out the disposition of the conventional heat dissipation device on the PCB. Thus, disposition of the heat dissipation device on a PCB with varied height surface remains a problem.

### SUMMARY OF THE INVENTION

In view of this, a purpose of the invention is to provide a function module and its manufacturing method. A planarization member is utilized to planarize a circuit board with devices with varying heights, and a plate-type heat dissipation device can be easily disposed on the circuit board.

Another purpose of the invention is to uniformly distribute the temperature of the devices on the circuit board by the high thermal conductivity of the planarization member. Compared with the conventional method, the cost and the height are reduced.

In the invention, a function module is provided. The function module includes a circuit board, a first device, a second device, a planarization member, and a plate-type heat dissipation device. The circuit board includes a surface. The first device is disposed on the surface. The second device is disposed on the surface, and the height of the second device is higher than the height of the first device. The planarization member includes a flat surface, and is disposed on the surface in a manner such that the first device and the second device are surrounded by the planarization member. The height of the flat surface is not less than the height of the second device. The plate-type heat dissipation device is disposed on the flat surface.

In a preferred embodiment, the planarization member may be thermosetting polymer.

Furthermore, the planarization member may be polyimide or silicone.

In another preferred embodiment, the planarization member further includes a thermal-conductive material, and the thermal-conductive material may be AlN, SiC, BN, or ZnO.

In another preferred embodiment, the thermal conductivity of the planarization member is larger than 0.5 W/m·K.

In another preferred embodiment, the planarization member is covered by two protective layers disposed at opposite sides of the planarization member in a detachable manner. Alternatively, the planarization member may be directly adhered to one side of the plate- type heat dissipation device.

It is understood that the plate-type heat dissipation device may be a plate-type heat pipe, a micro fin, a vapor chamber, or a water-cooling device. The second device may be a CPU.

In the invention, a method for manufacturing a function module is provided. The method includes the following steps. A circuit board and a plate-type heat dissipation device are provided. The circuit board includes a plurality of devices with varying heights thereon. A planarization member is placed on the circuit board, and the devices are surrounded by the planarization member. The planarization member is cured to form a flat surface, and the height of the flat surface is not less than the height of the devices. The plate-type heat dissipation device is placed on the flat surface.

In a preferred embodiment, the planarization member may be made of thermosetting polymer, polyimide, silicone or material with thermal conductivity larger than 0.5W/m·K.

In another preferred embodiment, the planarization member may be made of thermosetting polymer, polyimide, or silicone, and is mixed with a thermal-conductive material. The thermal-conductive material may be AlN, SiC, BN, or ZnO.

In another preferred embodiment, the planarization member is covered by two protective layers disposed at opposite sides of the planarization member in a detachable manner. Alternatively, the planarization member may be directly adhered to one side of the plate-type heat dissipation device.

Furthermore, one protective layer is separated from the planarization member before the planarization member is disposed on the circuit board. The other protective layer is separated from the planarization member before or after the planarization member is cured.

It is understood that the plate-type heat dissipation device may a plate-type heat pipe, a micro fin, a vapor chamber, or a water-cooling device.

In another preferred embodiment, the planarization member is cured by heating, infrared rays irradiation, or ultraviolet rays irradiation. Alternatively, the planarization member can be maintained in a gel state (jelly state) during the manufacture of the function module.

### BRIEF DESCRIPTION OF THE DRAWINGS

The present invention can be more fully understood by reading the subsequent detailed description and examples with references made to the accompanying drawings, wherein:

FIG. 1a is a schematic view of a conventional computer system;

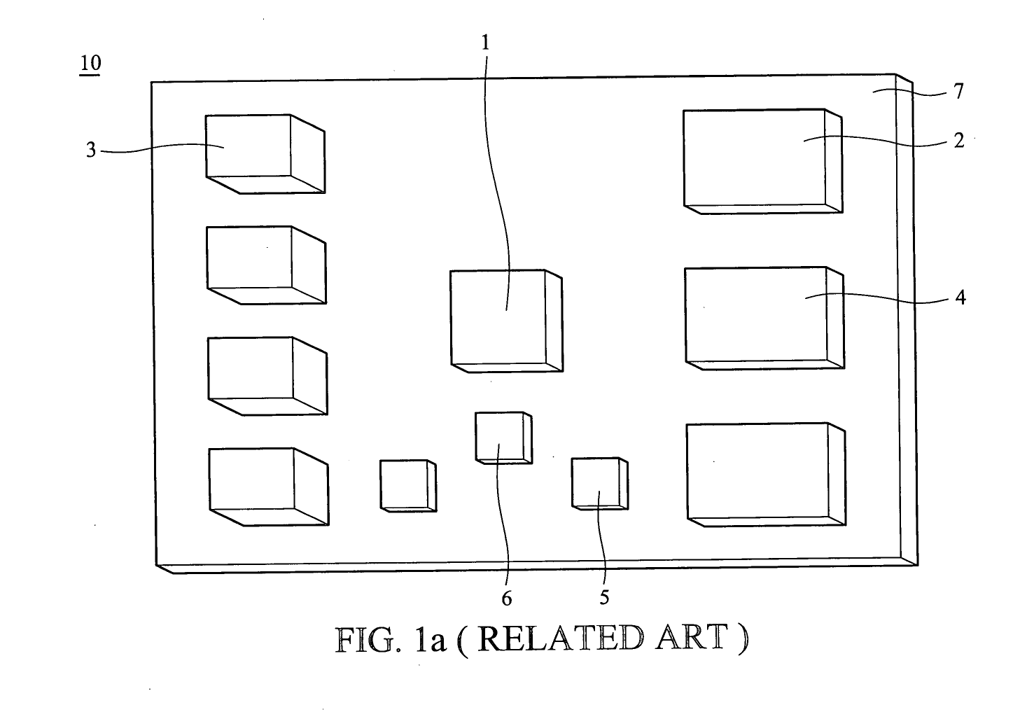

FIG. 1b is a side view showing the computer system in FIG. 1a;

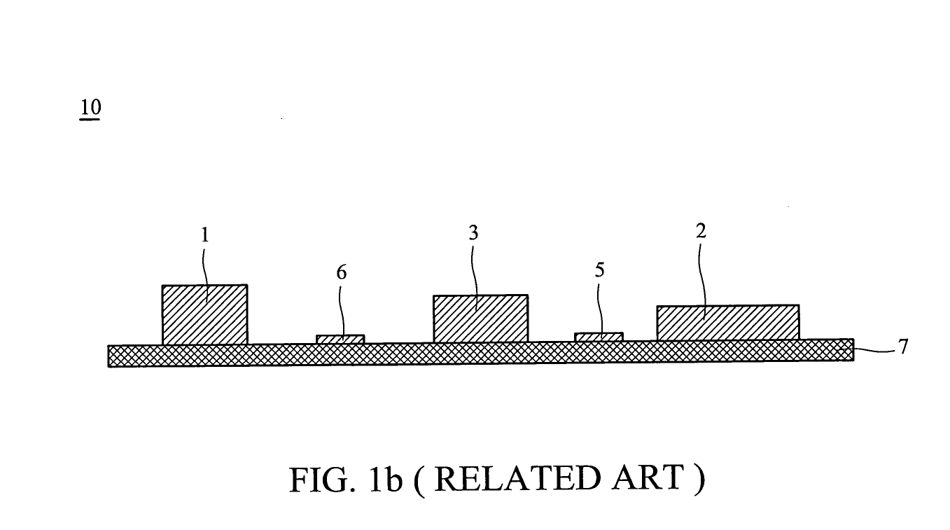

FIG. 2 is a schematic view showing a plate-type heat dissipation device disposed on a function module;

FIG. 3 is a schematic view showing the plate-type heat dissipation device and a height-compensation device disposed on a function module;

FIGS. 4a-4c are schematic views showing a method for manufacturing a function module as disclosed in a first embodiment of this invention;

FIG. 5a is a schematic view showing a variant embodiment of a planarization member in FIG. 4b;

FIG. 5b is a schematic view showing another variant embodiment of a planarization member in FIG. 4b; and

FIGS. 6a-6c are schematic views showing a method for manufacturing a function module as disclosed in a second embodiment of this invention.

### DETAILED DESCRIPTION OF THE INVENTION

### First Embodiment

In this embodiment, a planarization member is utilized to solve the problem of varying heights of devices on a motherboard. Also, plate-type heat dissipation devices such as plate-type heat pipes, vapor chambers, micro fins, water cooling devices, are utilized to improve heat dissipation in the devices on the motherboard.

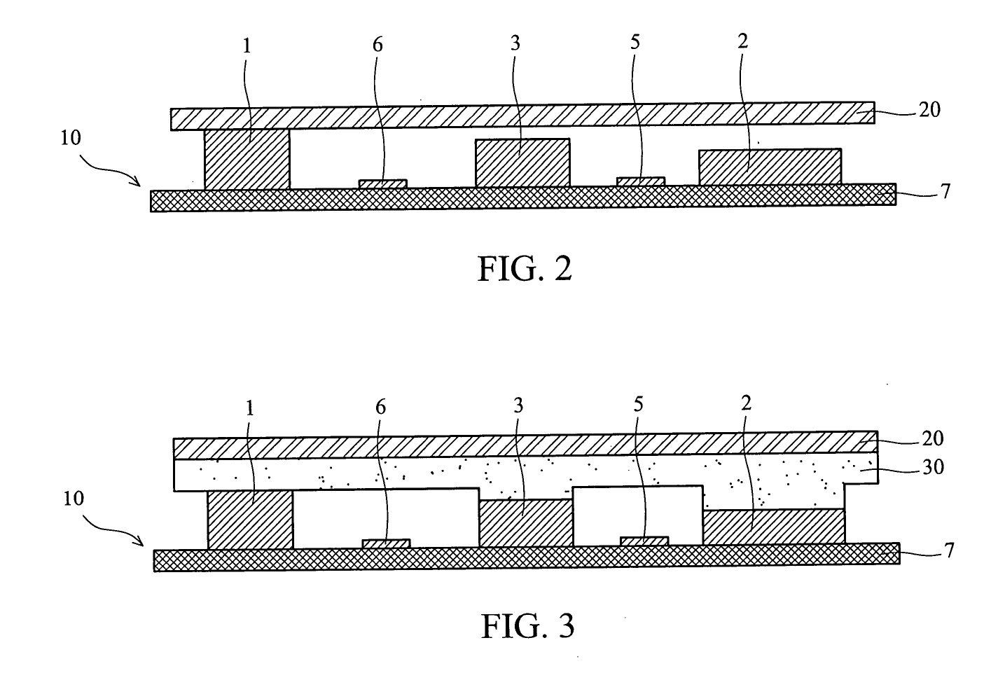

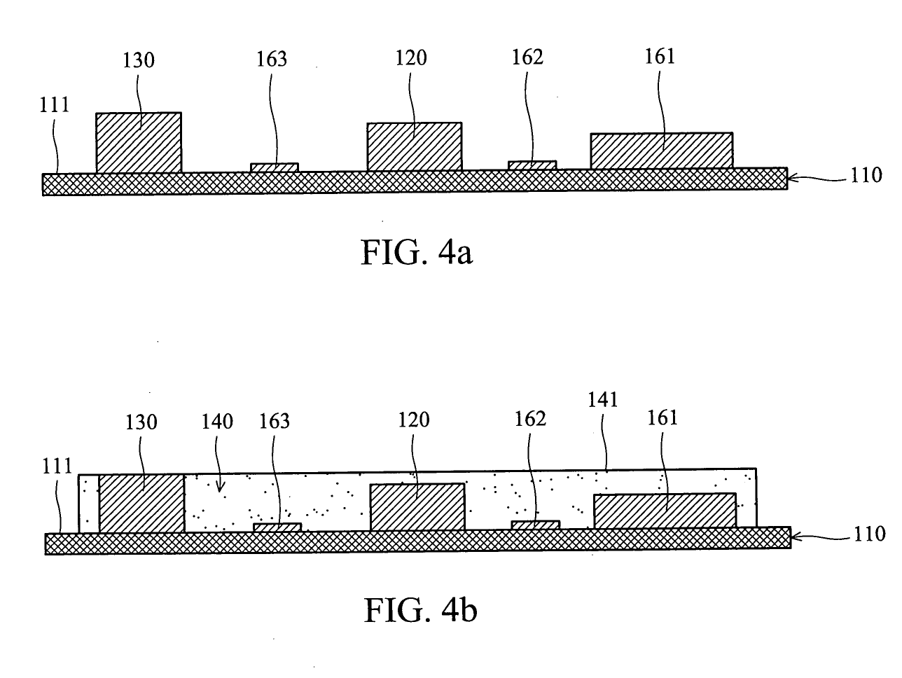

Referring to FIG. 2, a plate-type heat dissipation device 20 is disposed on a computer system 10 including a CPU 1, a chipset 2, a GPU 3, a memory 4, a resistor 5, a capacitor 6, and a motherboard 7. Due to varying heights of the devices, the plate-type heat dissipation device 20 cannot simultaneously dissipate the heat from each device. Referring FIG. 3, a height compensation member 30 is disposed on the computer system 10 to achieve uniform device height. Thus, the main devices such as the CPU 1, the north bridge 2, the GPU 3, are thermally connected to the height compensation member 30, and the plate-type heat dissipation device 20 is disposed on the is height compensation member 30.

To simultaneously and effectively dissipate the heat from high temperature devices, these devices are centralized in a specific area on the motherboard or are modulized in this embodiment. Then, the planarization member and the plate-type heat dissipation device are utilized to simultaneously solve the heat dissipation problem and the problem about the varying height of the devices.

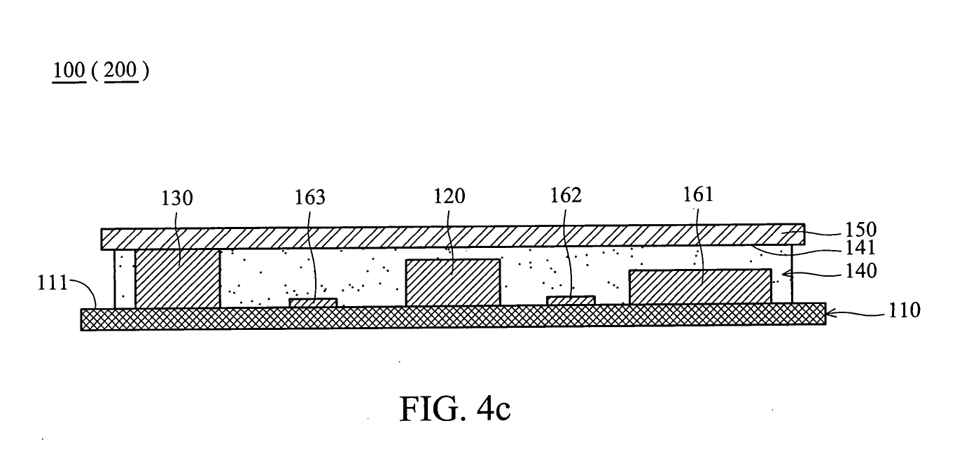

FIGS. 4a-4c show a method for manufacturing a function module as disclosed in this embodiment. The method includes the following steps. First, a circuit board 110 as shown in FIG. 4a and a plate-type heat dissipation device 150 as shown in FIG. 4c are provided. The circuit board 110 includes a plurality of devices 120, 130, 161, 162, 163 of varying height thereon. Specifically, the circuit board 110 has been tested and populated with devices by surface mount technology (SMT). Then, as shown in FIG. 4b, a planarization member 140 is placed on the circuit board 110, and the devices 120, 130, 161, 162, 163 are surrounded by the planarization member 140. It is noted in this embodiment that the planarization member 140 may be made of polymer material. Thus, the planarization member 140 may be provided with certain fluidity, and is able to fill in gaps between the devices 120, 130, 161, 162, 163 on the circuit board 110. A flat surface 141 is sequentially formed on the planarization member 140, and the height of the flat surface 141 is not less than the height of the highest devices 130. It is noted that the flat surface 141 can be formed by curing the planarization member 140 or maintaining the planarization member in a gel state. The planarization member 140 may be cured by heating, infrared, or ultraviolet light irradiation. Finally, the plate-type heat dissipation device 150 is placed on the flat surface 141 so as to obtain the function module 100 of this embodiment. The function module 100 may be considered as an area on the motherboard in which high temperature devices are centralized.

The planarization member 140 is located between the plate-type heat dissipation device 150 and the devices 120, 130, 161, 162, 163. To prevent the devices 120, 130, 161, 162, 163 on the motherboard 110 from short-circuiting, the planarization member 140 must provide insulation. Thus, the planarization member 140 may be made of insulating material with high resistivity, such as thermosetting polymer, polyimide, silicone or the combination of polyimide and silicone.

To enhance temperature uniformity in the entire function module 100, the planarization member 140 may further be provided with high thermal conductivity. Specifically, the planarization member 140 may be made of a material with thermal conductivity greater than 0.5 W/m·K.

As stated above, the planarization member 140 provides better insulation. However, to increase the thermal conductivity of the planarization member 140, the planarization member 140 may be mixed with an insulating material with high thermal conductivity. For example, ceramic material such as aluminum nitride (AlN), silicon carbide (SiC), boron nitride BN, zinc oxide (ZnO) or the combination of AlN, SiC, BN and ZnO can be utilized. It is noted that the planarization member 140 may be made of a material with high thermal conductivity and high resistivity such as polyimide, silicone or the combination of polyimide and silicone.

In addition, the plate-type heat dissipation device 150 may be a plate-type heat pipe, a micro fin, a vapor chamber, a water-cooling device or the combination of what mentioned above.

Furthermore, as stated above, although the planarization member 140 can be fluid, it must be sufficiently thick so that the planarization member 140 is prevented from flowing out of the circuit board 110 before the planarization member 140 is cured. However, to actually prevent the planarization member 140 from flowing out of the area of the circuit board 110 prior to curing, stoppers (not shown) can be disposed on the periphery of the circuit board 110.

As shown in FIG. 4c, the function module 100 in this embodiment includes a circuit board 110, a first device 120, a second device 130, a planarization member 140, a plate-type heat dissipation device 150, and other devices 161, 162, 163. The circuit board 110 includes a surface 111. The first device 120 and the second device 130 are disposed on the surface 111, and the height of the second device 130 is higher than the height of the first device 120. The planarization member 140 includes a flat surface 141, and is disposed on the surface 111 in a manner such that the first device 120, the second device 130, and the other devices 161, 162, 163 are surrounded by the planarization member 140. The height of the flat surface 141 is not less than the height of the second device 130. The plate-type heat dissipation device 150 is disposed on the flat surface 141.

It is understood that the first device 120 may be an active or passive component with lower height, and the second device 130 may be an active or passive component with higher height such as the CPU.

As stated above, in this embodiment, after the circuit board is populated with devices by SMT, the planarization member is utilized to planarize the function module so as to provide uniform device height. Thus, the plate-type heat dissipation device can be easily disposed on the function module to uniformly distribute the temperature and transfer the thermal energy without requiring a height compensation member.

In addition, since the planarization member is provided with high conductivity, the temperature of the function module can be uniformly distributed. Compared with the conventional method, the cost and the height are reduced.

### SECOND EMBODIMENT

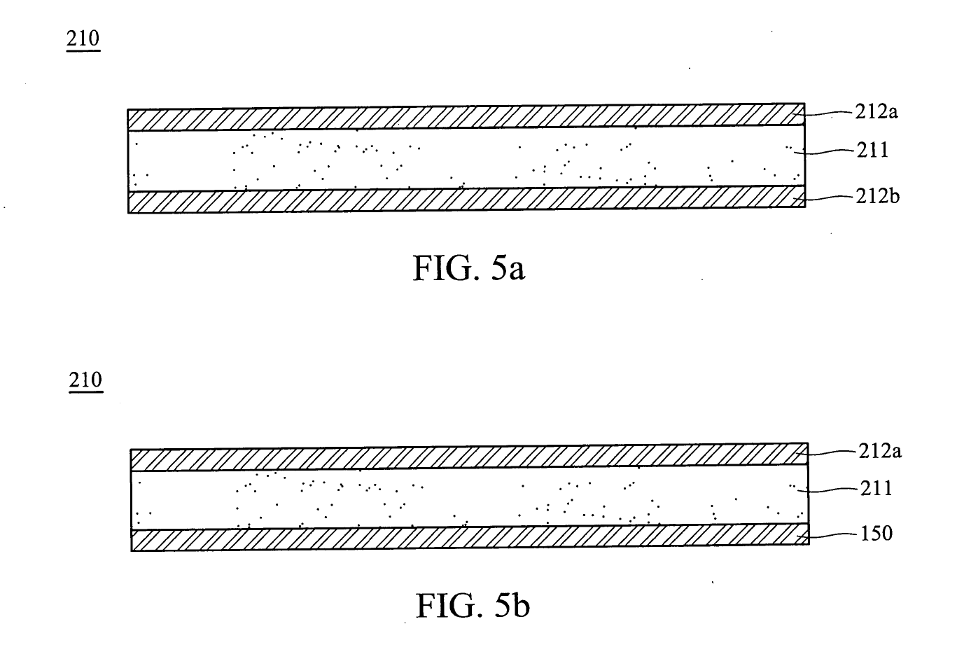

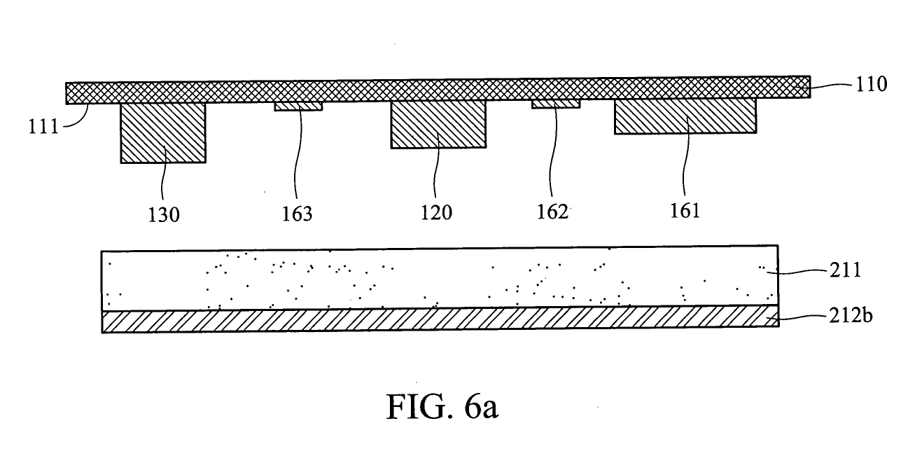

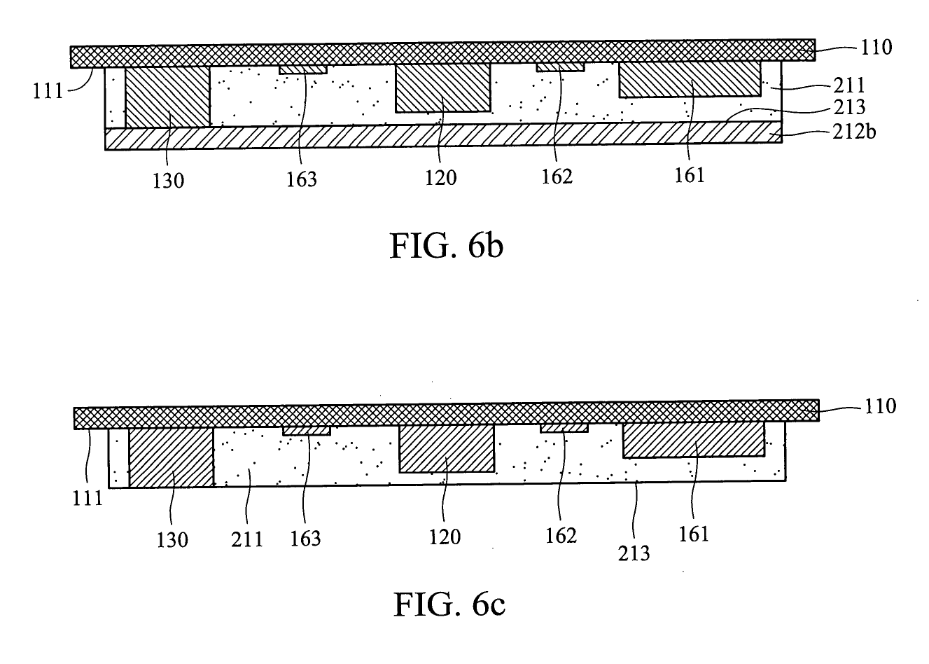

FIGS. 6a-6c show a method for manufacturing a function module as disclosed in this embodiment. The method includes the following steps. First, a circuit board 110 as shown in FIG. 4a and a plate-type heat dissipation device 150 as shown in FIG. 4c are provided. Since both the circuit board 110 and the plate-type heat dissipation device 150 are the same as those in the first embodiment, their description is omitted. Then, a planarization assembly 210 as shown in FIG. 5a is provided. It is noted that the planarization assembly 210 includes a sandwich-type structure with a planarization member 211 and two protective layers 212a and 212b covering the planarization member 210. The protective layers 212a and 212b are disposed at opposite sides of the planarization member 211 in a detachable manner. That is, both of the protective layers 212a and 212b can be separated from the planarization member 211. In addition, it is understood that the characteristics of the planarization member 211 are the same as that of the planarization member 140 in the first embodiment, and its detailed description is omitted. Then, as shown in FIG. 6a, the protective layer 212a is separated from the planarization member 211. The planarization member 211 is combined with the circuit board 110, and the devices 120, 130, 161, 162, and 163 are surrounded by the planarization member 211 as shown in FIG. 6b. The planarization member 211 is sequentially cured to form a flat surface 213, or the planarization member 211 is maintained in a gel state and formed a flat surface 213.

Finally, another protective layer 212b is separated from the protective member 211 as shown in FIG. 6c, and the plate-type heat dissipation device 150 is placed on the flat surface 213 so as to obtain the function module 200 of the embodiment as shown in FIG. 4c. It is understood that the protective layer 211b can be separated from the is planarization member 211 before or after the planarization member 211 is cured.

In addition, the planarization member 211 may be directly assembled with the plate-type heat dissipation device 150 as shown in FIG. 5b, and the protective layer 212b in FIG. 5a is replaced by the plate-type heat dissipation device 150. That is, the planarization assembly 210 includes a planarization member 211, a protective layer 212a, and a plate-type heat dissipation device 150. The protective layer 212a and the plate-type heat dissipation device 150 are located at opposite sides of the planarization member 211. That is, the protective layer 212a is disposed at one side of the planarization member 211 in a detachable manner, and the plate-type heat dissipation device 150 is disposed at another side of the planarization member 211. The protective layer 212a can be separated from the planarization member 211.

To manufacture the function module via the planarization assembly 210 as shown in FIG. 5b, the protective layer 212b as shown in FIG. 6a is replaced by the plate-type heat dissipation device 150. First, the protective layer 212a is separated from the planarization member 211. The planarization member 211 is combined with the circuit board 110, and the devices 120, 130, 161, 162, 163 are surrounded by the planarization member 211 as shown in FIG. 6b. Sequentially, the planarization member 211 is cured to form a flat surface 213, or the planarization member 211 is maintained in a gel state and forms a flat surface 213. Finally, since the plate-type heat dissipation device 150 is already in place on the flat surface 213, the function module 200 of this embodiment as shown in FIG. 4c can be obtained.

Compared the method in this embodiment with that in the first embodiment, the planarization member in the first embodiment is replaced by the planarization assembly in this embodiment. Thus, the function of the first embodiment can also be attained in this embodiment.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A function module comprising:
a circuit board including a surface;
a first device disposed on the surface;
a second device disposed on the surface, wherein the height of the second device is higher than the height of the first device; and
a planarization member, including a flat surface, disposed on the surface in a manner such that the first device and the second device is surrounded by the planarization member, wherein the height of the flat surface is not less than the height of the second device; and
a plate-type heat dissipation device disposed on the flat surface.

2. The function module as claimed in claim 1, wherein the planarization member is made of insulating material.

3. The function module as claimed in claim 2, wherein the insulating material is a thermosetting polymer.

4. The function module as claimed in claim 3, wherein the insulating material comprises one selected from the group consisting of polyimide, silicone and the combination thereof.

5. The function module as claimed in claim 2, wherein the planarization member further includes a thermal-conductive material.

6. The function module as claimed in claim 5, wherein the thermal-conductive material comprises one selected from the group consisting of AlN, SiC, BN, ZnO and the combination thereof.

7. The function module as claimed in claim 1, wherein the plate-type heat dissipation device is a plate-type heat pipe, a micro fin, a vapor chamber, or a water-cooling device.

8. The function module as claimed in claim 1, wherein the second device is a CPU.

9. A method for manufacturing a function module, comprising:
providing a circuit board and a plate-type heat dissipation device, wherein the circuit board includes a plurality of devices with varying heights thereon;
placing a planarization member on the circuit board so that the devices are surrounded by the planarization member;
curing the planarization member so as to form a flat surface, wherein the height of the flat surface is not less than the height of the devices; and
placing the plate-type heat dissipation device on the flat surface.

10. The method as claimed in claim 9, wherein the planarization member is made of insulating material.

11. The method as claimed in claim 10, wherein the insulating material is a thermosetting polymer.

12. The method as claimed in claim 11, wherein the insulating material comprises one selected from the group consisting of polyimide, silicone and the combination thereof.

13. The method as claimed in claim 10, wherein the planarization member further includes a thermal-conductive material.

14. The method as claimed in claim 13, wherein the thermal-conductive material comprises one selected from the group consisting of AlN, SiC, BN, ZnO and the combination thereof.

15. The method as claimed in claim 9, wherein the planarization member is covered by two protective layers, and the protective layers are disposed at opposite sides of the planarization member in a detachable manner.

16. The method as claimed in claim 15, wherein one of the protective layers is separated from the planarization member before the planarization member is disposed on the circuit board, and another protective layer is separated from the planarization member before the planarization member is cured.

17. The method as claimed in claim 15, wherein one of the protective layers is separated from the planarization member before the planarization member is disposed on the circuit board, and another protective layer is separated from the planarization member after the planarization member is cured.

18. The method as claimed in claim 9, wherein the plate-type heat dissipation device is a plate-type heat pipe, a micro fin, a vapor chamber, or a water-cooling device.

19. The method as claimed in claim 9, wherein the planarization member is cured by heating the planarization member.

20. The method as claimed in claim 9, wherein the planarization member is cured by infrared light irradiation.

21. The method as claimed in claim 9, wherein the planarization member is cured by ultraviolet light irradiation.

22. A method for manufacturing a function module, comprising:
providing a circuit board and a plate-type heat dissipation device, wherein the circuit board includes a plurality of devices with varying heights thereon;
placing a planarization member on the circuit board so that the devices are surrounded by the planarization member;
forming a flat surface on the planarization member, wherein the height of the flat surface is not less than the height of the devices; and
placing the plate-type heat dissipation device on the flat surface.

23. The method as claimed in claim 22, wherein the planarization member is made of insulating material.

24. The method as claimed in claim 23, wherein the insulating material is a thermosetting polymer.

25. The method as claimed in claim 24, wherein the insulating material comprises one selected from the group consisting of polyimide, silicone and the combination thereof.

26. The method as claimed in claim 23, wherein the planarization member further includes a thermal-conductive material.

27. The method as claimed in claim 26, wherein the thermal-conductive material comprises one selected from the group consisting of AlN, SiC, BN, ZnO and the combination thereof.

28. The method as claimed in claim 22, wherein the planarization member is covered by a protective layer and the plate-type heat dissipation device, and the protective layer and the plate-type heat dissipation device are disposed at opposite sides of the planarization member.

29. The method as claimed in claim 28, wherein the protective layer is separated from the planarization member before the planarization member is disposed on the circuit board.

30. The method as claimed in claim 22, wherein the plate-type heat dissipation device is a plate-type heat pipe, a micro fin, a vapor chamber, or a water-cooling device.
